(19) United States
(12) Patent Application Publication
(10) Pub. No.: US 2023/0357997 A1
(43) Pub. Date: Nov. 9, 2023

(54) MONITORING INSULATION RESISTANCE OF A SCREED ASSEMBLY OF A PAVING MACHINE

(71) Applicant: Caterpillar Paving Products Inc., Brooklyn Park, MN (US)

(72) Inventors: Ryan T. THIESSE, Otsego, MN (US); Matthew E. BUSCH, Becker, MN (US)

(73) Assignee: Caterpillar Paving Products Inc., Brooklyn Park, MN (US)

(21) Appl. No.: 17/738,634

(22) Filed: May 6, 2022

(51) Int. Cl. E01C 19/42; B60Q 5/00; B60Q 9/00; G01R 31/12

(52) U.S. Cl. CPC E01C 19/42; B60Q 5/005; B60Q 9/00; G01R 31/1272; E01C 2301/10; E01C 2301/00

(57) ABSTRACT

A method may include determining, by a controller of a paving machine, to start a test of one or more heaters associated with a screed assembly of the paving machine. The method may further include sending, by the controller and to a tester device associated with the paving machine, one or more signals configured to cause a test voltage to be generated while the one or more heaters are sequentially turned off and then on during the test. The method may further include receiving, by the controller, a measurement of an insulation resistance of each of the one or more heaters during the test. The method may further include performing, by the controller, one or more actions based on a result of processing the measurement.

### TECHNICAL FIELD

The present disclosure relates generally to monitoring a screed assembly of a paving machine, and more particularly, to monitoring insulation resistance of the screed.

### BACKGROUND

The present disclosure relates to paving machines that are used in road surface construction and repairs. Paving machines are typically utilized to lay asphalt or other paving material. Paving machines generally include a screed assembly for spreading and compacting a mat of paving material relatively evenly over a desired surface. During paving, screed plates in the screed assembly are heated to prevent asphalt from sticking to the screed plates as the asphalt is compacted. As such, during paving operations, it is important to try to identify heaters on the screed assembly that are faulty or likely to experience a fault.

EP Patent No. 3051024B1, granted on Nov. 21, 2018 (“the '024 patent”), describes a method for monitoring a plank heater of a road finishing machine. In particular, the '024 patent describes switching off all heating sections with the exception of the heating section on which a different temperature is measured. For the heating section that is kept on, the method then turns off all but a few heating elements. If the heating elements operate correctly, an operator can determine that the malfunction is located at a different location. However, by requiring that all but a faulty heating section, or all but a few heating elements of the heating section, be turned off, the method of the '024 patent cannot identify and isolate faults during operation of a paving machine.

The present disclosure may solve one or more of the problems set forth above and/or other problems in the art. The scope of the current disclosure, however, is defined by the attached claims, and not by the ability to solve any specific problem.

### SUMMARY

In one aspect, a method may include determining, by a controller of a paving machine, to start a test of one or more heaters associated with a screed assembly of the paving machine. The method may further include sending, by the controller and to a tester device associated with the paving machine, one or more signals configured to cause a test voltage to be generated while the one or more heaters are sequentially turned off and then on during the test. The method may further include receiving, by the controller, a measurement of an insulation resistance of each of the one or more heaters during the test. The method may further include performing, by the controller, one or more actions based on a result of processing the measurement.

In another aspect, a paving machine may include a screed assembly, one or more heaters associated with the screed assembly, a tester device, and a controller. The controller may be configured to determine to start a test of one or more heaters associated with the screed assembly of the paving machine. The controller may be further configured to send, to the tester device associated with the paving machine, one or more signals configured to cause a test voltage to be generated while the one or more heaters are sequentially turned off and then on during the test. The controller may be further configured to receive a measurement of an insulation resistance of each of the one or more heaters during the test. The method may be further configured to perform one or more actions based on a result of processing the measurement.

In yet another aspect, a controller for a paving machine may be configured to determine to start a test of one or more heaters associated with a screed assembly of the paving machine. The controller may be further configured to send, to a tester device associated with the paving machine, one or more signals configured to cause a test voltage to be generated while the one or more heaters are sequentially turned off and then on during the test. The controller may be further configured to receive a measurement of an insulation resistance of each of the one or more heaters during the test. The controller may be further configured to perform one or more actions based on a result of processing the measurement.

Other features and aspects of this disclosure will be apparent from the following description and the accompanying drawings.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 is a schematic view of an exemplary paving machine that includes a screed assembly and elements for monitoring the screed assembly, according to aspects of the disclosure.

FIG. 2 is a diagram illustrating an exemplary system architecture for monitoring insulation resistance of a screed assembly of a paving machine, according to aspects of the disclosure.

FIG. 3 illustrates a flowchart depicting an exemplary method for monitoring insulation resistance of a screed assembly of a paving machine, according to aspects of the disclosure.

### DETAILED DESCRIPTION

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value.

For the purpose of this disclosure, the term “ground surface” is broadly used to refer to all types of surfaces that form typical roadways (e.g., asphalt, cement, clay, sand, dirt, etc.) or upon which paving material may be deposited in the formation of roadways. Although the current disclosure is described with reference to a paving machine, this is only exemplary. In general, the current disclosure can be applied to any machine that uses a screed-type assembly.

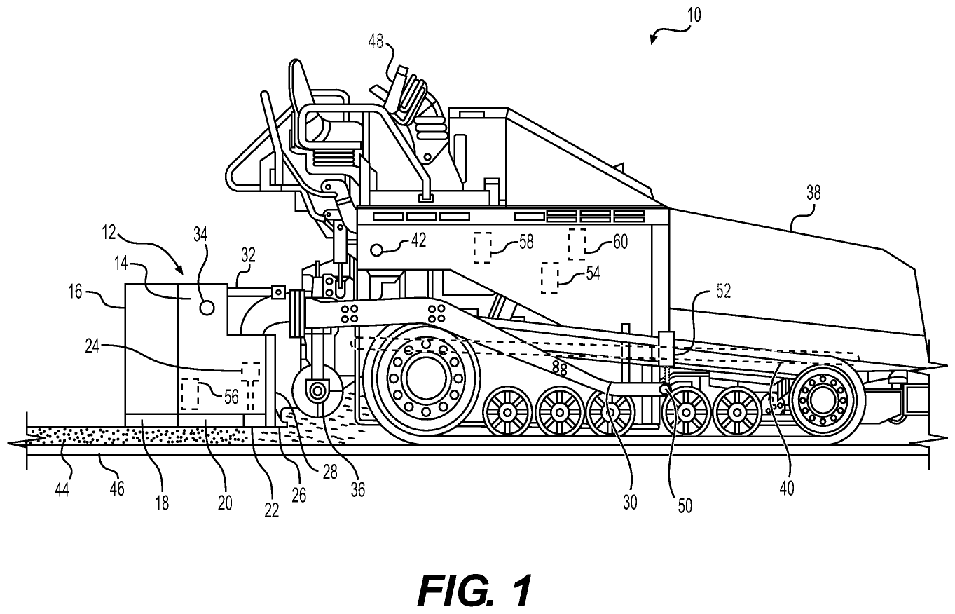

FIG. 1 is a schematic view of an exemplary paving machine 10 that includes a screed assembly 12 and elements for monitoring the screed assembly 12, according to aspects of the disclosure. The paving machine 10 may deposit or pave a mat 44 on a base 46. The paving machine 10 may include a screed assembly 12 and a pair of tow arms 30 (only one of which is visible in FIG. 1) attached to the screed assembly 12 and tow points 50 located on a frame of the paving machine 10, as shown in FIG. 1. The tow arms 30 may be attached to a pair of tow point cylinders 52 (only one of which is visible in FIG. 1). The tow point cylinders 52 may be configured to control the height of the tow points 50 by adjusting hydraulic pressures within the tow point cylinders 52, thereby controlling the height of the tow arms 30. The paving machine 10 may further include a hopper 38 adapted for storing a paving material such as asphalt, and a conveyor system including one or more conveyors 40 configured for moving the paving material from the hopper 38 to the screed assembly 12 to a rear of the paving machine 10. One or more augers 36 may be arranged near a forward end of the screed assembly 12 to receive the paving material provided by the conveyor 40 and spread the paving material evenly beneath the screed assembly 12. The paving machine 10 may also include an inclinometer 42 attached to the frame of the paving machine 10, as shown in FIG. 1. The inclinometer 42 may measure the angle at which the paving machine 10 travels on the base 46 (e.g., a ground surface). Additionally, the paving machine 10 may include a display 48 for providing visual feedback of operation controls and/or conditions of the paving machine 10.

As further shown in FIG. 1, the screed assembly 12 may be pivotally connected (at the tow point 50) behind the paving machine 10 by the tow arms 30. The tow arms 30 may be configured to float so as to be raised and lowered as a function of the amount of paving material at an upstream end of the screed assembly 12. The relative position and orientation of the screed assembly 12 relative to the frame of the paving machine 10 and the mat 44 may be adjusted by adjusting the tow point 50 connected to the pivoting tow arms 30, in order, for example, to control the thickness of the paving material deposited via the paving machine 10 and to adjust the angle of attack of the screed assembly 12. The screed assembly 12 may include a main screed 14 and screed extenders 16 (only one of which is illustrated in FIG. 1). The screed extenders 16 may be configured, by a screed extender control 32, to be slidably movable laterally relative to the main screed 14 between retracted and extended positions so that varying widths of paving material can be laid. The screed extenders 16 may include an extender screed plate 18.

The main screed 14 may include a main screed plate 20, a tamper bar 22, a deflector 28, and a pre-strikeoff 26. The tamper bar 22 may be connected to a tamper bar controller 24 that is configured to move the tamper bar 22 up and down so as to be able to strike the surface of the paving material after it is deposited by one or more augers 36. The tamper bar 22 may provide compaction of the paving material as well as affecting the angle of attack of the screed assembly 12. The pre-strikeoff 26 may be attached (e.g., by welding) to the deflector 28. The height of the pre-strikeoff 26, which may affect the angle of attack of the screed assembly 12, may be adjustable vertically by moving the deflector 28 vertically up and down. The main screed 14 may also include the inclinometers 34 (only one of which is shown in FIG. 1) in order to measure the angle of attack of the screed assembly 12 relative to the mat 44, and the cross slope or twist angle of the main screed 14.

The paving machine 10 may include a controller 54. Controller 54 may include a processor and a memory (the processor and memory are not shown in FIG. 1). The processor may include a central processing unit (CPU), a graphics processing unit (GPU), a microprocessor, a digital signal processor and/or other processing units or components. Additionally, or alternatively, the functionality described herein can be performed, at least in part, by one or more hardware logic components. For example, and without limitation, illustrative types of hardware logic components that may be used include field-programmable gate arrays (FPGAs), application-specific integrated circuits (ASICs), application-specific standard products (ASSPs), system-on-a-chip systems (SOCs), complex programmable logic devices (CPLDs), etc. Additionally, the processor may possess its own local memory, which also may store program modules, program data, and/or one or more operating systems. The processor may include one or more cores.

The memory may be a non-transitory computer-readable medium that may include volatile and/or nonvolatile memory, removable and/or non-removable media implemented in any method or technology for storage of information, such as computer-readable instructions, data structures, program modules, or other data. Such memory includes, but is not limited to, random access memory (RAM), read-only memory (ROM), electrically erasable programmable read-only memory (EEPROM), flash memory or other memory technology, compact disc read-only memory (CD-ROM), digital versatile discs (DVD) or other optical storage, magnetic cassettes, magnetic tape, magnetic disk storage or other magnetic storage devices, redundant array of independent disks (RAID) storage systems, or any other medium which can be used to store the desired information and which can be accessed by a computing device (e.g., the display 48, a server device remote to the paving machine 10, etc.). The memory may be implemented as computer-readable storage media (CRSM), which may be any available physical media accessible by the processor to execute instructions stored on the memory. The memory may have an operating system (OS) and/or a variety of suitable applications stored thereon. The OS, when executed by the processor, may enable management of hardware and/or software resources of the controller 54.

The memory may be capable of storing various computer readable instructions for performing certain operations described herein. The instructions, when executed by the processor, may cause certain operations described herein to be performed.

As further illustrated in FIG. 1, the paving machine 10 may include one or more heaters 56. For example, the screed assembly 12 may include one or more zones, and each of the zones may have one or more associated heaters 56 for heating screed plates 18, 20 in the zones. The controller 54 and/or a tester device 60 may test one or more of the heaters 56 during operation of the paving machine 10, as described in more detail elsewhere herein. One or more power modules 58 may provide electrical power to the heaters 56, and the controller 54 and/or tester device 60 may control the power modules 58.

The tester device 60 may include a processor and memory, similar to that described with respect to the controller 54. The tester device 60 may, based on a command from the controller 54, execute instructions or testing sequences to test the one or more heaters 56. For example, and as described herein, the tester device 60 may sequentially turn off and then on the heaters 56 while generating a test voltage, and may measure an insulation resistance of the heaters 56.

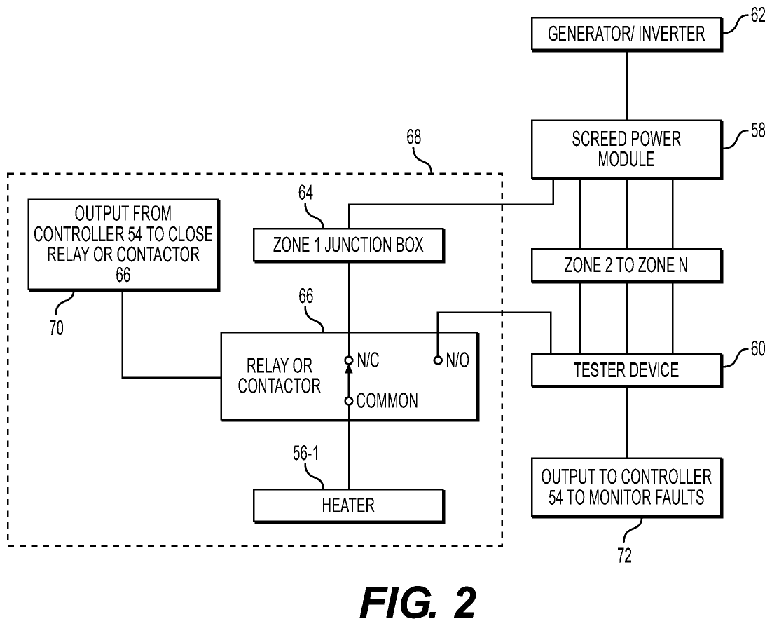

FIG. 2 is a diagram illustrating an exemplary system architecture for monitoring insulation resistance of the screed assembly 12 of the paving machine 10, according to aspects of the disclosure. As illustrated in FIG. 2, the system architecture may include a generator/inverter 62 (e.g., a generator, an inverter, or a combined generator and inverter). The generator/inverter 62 may convert mechanical energy to electrical energy (in the case of a generator) and/or may convert electrical energy from one form into another in the case of an inverter (e.g., converts direct current to alternating current). The generator/inverter 62 may output electrical energy to the screed power module 58. The power module 58 may control supply of electrical energy to one or more heating zones 68. FIG. 2 illustrates a detailed view of a first heating zone 68 (zone 1), and FIG. 2 illustrates that the system architecture may include one or more other heating zones 68 (zone 2 to zone N).

The first heating zone 68 may include a junction box 64 (e.g., a “zone 1 junction box” for the first zone 68). The junction box 64 may include circuitry to electrically connect one or more elements of the heating zone 68 to one or more other elements of the paving machine 10. The heating zone 68 may further include a relay or contactor 66 that includes circuitry that electrically connects a heater 56 in the zone 1 (heater 56-1) to the junction box 64 and the tester device 60. In particular, the relay or contactor 66 may include switching circuitry that selectively connects the heater 56-1 to the junction box 64 or to the tester device 60, depending on output 70 (e.g., commands) from the controller 54 to close the relay or contactor 66. For example, the relay or contactor 66 may switch a common electrical connection (labeled “common” in FIG. 2) from a normally closed (“N/C”) connection to the junction box 64 to a normally open (“N/O”) connection to the tester device 60.

When the common electrical connection is switched to the N/O electrical connection, the tester device 60 may perform a test of the heater 56-1, as described in more detail elsewhere herein. The tester device 60 may further include electrical connections to provide output 72 to the controller 54 for fault monitoring and/or for taking actions.

### INDUSTRIAL APPLICABILITY

The disclosed aspects of the controller 54, the tester device 60, and/or a remote server device of the present disclosure, and in particular, the methods executed by the controller 54, the tester device 60, and/or the server device may be used to monitor insulation resistance of a screed assembly 12 of a paving machine 10. For example, the methods executed by the controller 54, the tester device 60, and/or the server device may control when the tester device 60 performs a test of one or more heaters 56, may control a manner in which the tester device 60 performs the test, may process results of the test to identify faulty heaters 56 or heaters 56 that are at risk of experiencing faults, may perform one or more actions to protect the paving machine 10 from damage as a result of the detected faults (or potential faults), and/or the like. Thus, certain embodiments described herein may provide various advantages to the operation of a paving machine 10, such as fault reduction, damage prevention, and/or the like, which may reduce downtime of the paving machine 10, may reduce or eliminate disruptions to operations at a worksite that might otherwise occur as a result of unexpected faults of the paving machine 10, and/or the like. In addition, certain embodiments described herein may perform certain operations while the paving machine 10 is in use, or when the paving machine 10 is started, which may increase an efficiency of using the paving machine 10 by reducing or eliminating a need for the paving machine 10 to be pulled out of service for testing. Additionally, or alternatively, certain embodiments described herein may be capable of measuring the insulation resistance of each heater 56 in real time, which may reduce a response time for taking a corrective or preventative action after detecting a fault or potential fault.

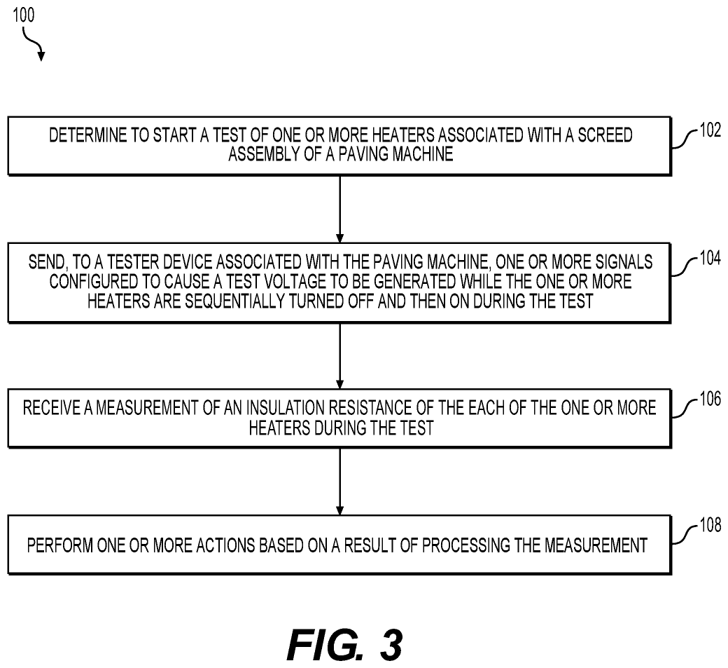

FIG. 3 illustrates a flowchart depicting an exemplary method 100 for monitoring insulation resistance of a screed assembly 12 of a paving machine 10. The method 100 illustrated in FIG. 3 may be implemented by the controller 54. In some embodiments, one or more steps of the method 100 may be performed by the tester device 60 and/or by a server device remote to the paving machine 10 (e.g., a server device located at a control center for a work site, located in a data center, and/or the like). The steps of the method 100 described herein may be embodied as machine readable and executable software instructions, software code, or executable computer programs stored in the memory and executed by the processor of the controller 54 (or of the tester device 60 or the server device). The software instructions may be further embodied in one or more routines, subroutines, or modules and may utilize various auxiliary libraries and input/output functions to communicate with other equipment. The method 100 illustrated in FIG. 3 may also be associated with an operator interface (e.g., a human-machine interface, such as a graphical user interface (GUI)) through which an operator of the paving machine 10 or a worksite may control the paving machine 10, may configure a test of a heater 56, and/or the like. Therefore, the method 100 may be implemented by the controller 54 (or the tester device 60 or the server device) to monitor insulation resistance of the screed assembly 12 of the paving machine 10, for example.

At step 102, the method 100 may include determining to start a test of one or more heaters 56 associated with a screed assembly 12 of a paving machine 10. For example, the controller 54 may determine to start the test based on input from an operator of the paving machine 10 (e.g., input provided via the display 48), based on start-up of the paving machine 10 (or boot-up of a system, such as a diagnostic system, of the paving machine 10), based on receiving a command from a remote control center via a wireless network, and/or the like. Additionally, or alternatively, the controller 54 may determine to start the test at a predetermined or scheduled time based on a configuration stored by the controller 54 or based on information included in a command to start the test.

In some embodiments, the controller 54 may determine the test to be performed. For example, the controller 54 may determine a subset of one or more available tests to be performed based on an age, number, configuration, hours of usage, and/or the like of the heaters 56. Continuing with the previous example, the controller 54 may select a test that tests each heater 56 more frequently than another test that just tests the heaters 56 on start-up of the paving machine 10 based on the heaters 56 being older than a certain age. Additionally, or alternatively, the controller 54 may determine certain heaters 56 for which a test is to be performed based on characteristics of the heaters 56. For example, the controller 54 may select one or more heaters 56 for testing by selecting heaters 56 that have a similar age, hours of usage, and/or the like. In some embodiments, the tester device 60, rather than the controller 54, may perform these determinations. These aspects may help to improve detection and/or prediction of a faulty heater 56.

In some embodiments, the controller 54 may receive a configuration of a test from an operator of the paving machine 10 via the display 48 or a server device via a wireless network, and the controller 54 may configure the tester device 60 to perform the test. For example, the controller 54 may send a message to the tester device 60 to configure the tester device 60. Alternatively, the tester device 60 may receive a configuration of the test directly from the off-board server device or the configuration may be pre-loaded on the tester device 60 during fabrication of the paving machine 10.

The method 100 may further include, at step 104, sending, to a tester device 60 associated with the paving machine 10, one or more signals configured to cause a test voltage to be generated while the one or more heaters 56 are sequentially turned off and then on during the test. For example, the controller 54 may send one or more commands to the tester device 60 to perform a test for certain heaters 56, to perform the test at a certain time, configurations for the test, and/or the like. A test may include testing one heater 56 at a time by turning off a first heater 56 (e.g., switching the relay or contactor 66 from an N/C connection to a N/O connection), generating a test voltage, measuring the insulation resistance of the heater 56, and then turning the first heater 56 on (e.g., switching the relay or contactor 66 from the N/O connection to the N/C connection) before testing one or more other heaters 56. By sequentially testing each heater 56 while other heaters 56 are on, certain embodiments may monitor the screed assembly 12 while the paving machine 10 is in operation and may help to precisely identify which heaters 56 are faulty.

At the scheduled time of the test, the controller 54 may send one or more signals to the relay or contactor 66 to switch an electrical connection from a junction box 64 to the tester device 60. Alternatively, the tester device 60 may send the one or more signals to the relay or contactor 66.

Upon receipt of the one or more signals, the tester device 60 may perform the test according to the configuration described above. For example, the tester device 60 may turn off a heater 56 under testing, generate a test voltage on an electrical connection with the heater 56, may measure the insulation resistance of the heater 56, and may then turn the heater 56 on. To measure the insulation resistance, the tester device 60 may measure current leakage using one or more sensors associated with the heater 56. During the test, the tester device 60 may store the measurements in memory.

At step 106, the method 100 may include receiving a measurement of an insulation resistance of the each of the one or more heaters during the test. For example, the controller 54 may receive the measurement from the tester device 60 for processing or for providing to an off-board server device for processing. The measurement received may include a stream of measurements from the tester device 60 or may receive measurements that have been pre-processed by the tester device 60. For example, the pre-processing may include the tester device 60 aggregating measurements over time or eliminating outlier measurements. In some embodiments, the controller 54 may receive un-processed data from the tester device 60 and may perform the pre-processing before sending the measurements to the off-board server device for further processing.

Upon receiving the measurement or after performing pre-processing, the controller 54 may process the measurements to detect a fault in the insulation resistance or to predict a fault in the insulation resistance. For example, this processing may include generating a degradation curve for the measurements for each heater 56 and may monitor whether the degradation curve falls below a threshold. Alternatively, the tester device 60 and/or the controller 54 may provide the measurements to an off-board server device (e.g., via a wireless network) to perform this processing. In this case, the off-board server device may provide a result of the processing to the controller 54 and/or tester device 60, may just provide alerts when the degradation curve falls below the threshold, and/or the like. Alternatively, the tester device 60 may process the measurements upon gathering the measurements from a sensor and may provide a result (or alerts based on the result) to the controller 54, rather than the controller 54 or the off-board server device performing the processing. In some embodiments, the controller 54, the tester device 60, and/or the off-board server device may provide the measurements, or a result of processing the measurements, for display via the display 48.

The method 100 may further include, at step 108, performing one or more actions based on a result of processing the measurement. For example, the controller 54 may perform the one or more actions based on a result of the processing indicating that the measurement has fallen below a threshold (e.g., a threshold indicating a fault in the insulation resistance or a threshold indicating that a fault is likely to occur within a certain amount of time), that the trend line for the measurement has a particular shape or slope, and/or the like. In some embodiments, the tester device 60 and/or an off-board server device may perform the one or more actions.

The one or more actions may include shutting down the paging machine 10, a heater 56, and/or a zone 68 of the screed assembly 12 when the measurement falls below a threshold. For example, the controller 54 may trip a ground fault. Additionally, or alternatively, the one or more actions may include modifying an operation of the paving machine 10. For example, if a heater 56, or a certain number of heaters 56, have faults, the controller 54 may send a command to raise the screed assembly 12 or adjust a position of the screed assembly 12. As another example, the controller 54 may send a command to power on one or more auxiliary heaters 56 or to increase the temperature of one or more heaters 56 adjacent to a faulty heater 56.

Additionally, or alternatively, the one or more actions may include providing an alert, alarm, or message for display via the display 48 when the measurement falls below a threshold. Similarly, the one or more actions may include providing, for display via the display 48, information that indicates a status of the insulation resistance (e.g., a high, medium, or low status), and updating the information in real-time or near real-time based on the result of the measurement.

Additionally, or alternatively, the one or more actions may include scheduling the paving machine 10 for maintenance. For example, the controller 54 and/or the off-board server device may access an electronic schedule for a maintenance facility and may generate a reservation on the schedule for maintenance of the paving machine 10. Additionally, or alternatively, the one or more actions may include sending a message to a device associated with a technician to perform maintenance or inspection of one or more heaters 56.

Although the method 100 illustrated in FIG. 3 is described as including steps 102 to 108, the method 100 may not include all of these steps or may include additional or different steps. For example, the method 100 may just include the steps 106 and 108.

Certain embodiments described herein may provide, for example, real-time or near real-time monitoring of an insulation resistance of a heater 56, which may reduce or eliminate damage to asphalt or a paving machine 10 that might occur as a result of latency in identifying faulty heaters. Similarly, certain embodiments may provide for early detection of a fault that is likely to occur, which may reduce interruptions to operations of the paving machine 10 and/or at a worksite. As another example, certain embodiments may provide for monitoring of the insulation resistance while the paving machine 10 is operating or upon start-up of the paving machine 10, which may reduce or eliminate a need to take the paving machine 10 to a maintenance facility for testing of the heaters 56. This may reduce downtime of the paving machine 10 for maintenance, may reduce the amount of time that the paving machine 10 needs to spend at a maintenance facility, and/or the like through accurate identification of a faulty heater 56 and/or by eliminating in-facility maintenance.

It will be apparent to those skilled in the art that various modifications and variations can be made to the disclosed system without departing from the scope of the disclosure. Other embodiments of the system will be apparent to those skilled in the art from consideration of the specification and practice of the system disclosed herein. It is intended that the specification and examples be considered as exemplary only, with a true scope of the disclosure being indicated by the following claims and their equivalents.

What is claimed is:

1. A method, comprising:
determining, by a controller of a paving machine, to start a test of one or more heaters associated with a screed assembly of the paving machine;
sending, by the controller and to a tester device associated with the paving machine, one or more signals configured to cause a test voltage to be generated while the one or more heaters are sequentially turned off and then on during the test;
receiving, by the controller, a measurement of an insulation resistance of each of the one or more heaters during the test; and
performing, by the controller, one or more actions based on a result of processing the measurement.

2. The method according to claim 1, wherein the one or more signals are further configured, when causing the one or more heaters to be sequentially turned off and then on, to cause a first heater to be turned off and then on prior to testing a second heater.

3. The method according to claim 1, wherein determining to start the test further comprises:
determining to start the test based on:
start-up of the paving machine,
input from an operator of the paving machine via a display of the paving machine,
one or more signals from a diagnostic system of the paving machine, or
one or more signals from a server device that is remote to the paving machine.

4. The method according to claim 1, wherein receiving the measurement further comprises:
receiving the measurement from the tester device; and
wherein the method further comprises:
providing the measurement to a server device remote from the paving machine for processing.

5. The method according to claim 1, further comprising:
generating a degradation curve based on the measurement; and
determining whether a heater is faulty or likely to experience a fault based on the degradation curve.

6. The method according to claim 1, wherein the one or more actions include stopping the paving machine or a heater, or
modifying an operation of the paving machine, the heater, or one or more other heaters.

7. The method according to claim 1, wherein the one or more actions include generating an alarm or a message for display on a display of the paving machine.

8. A paving machine, comprising:
a screed assembly,
one or more heaters associated with the screed assembly,
a tester device, and
a controller, wherein the controller is configured to:
determine to start a test of one or more heaters associated with the screed assembly of the paving machine;
send, to the tester device associated with the paving machine, one or more signals configured to cause a test voltage to be generated while the one or more heaters are sequentially turned off and then on during the test;
receive a measurement of an insulation resistance of each of the one or more heaters during the test; and
perform one or more actions based on a result of processing the measurement.

9. The paving machine according to claim 8, wherein the one or more signals are further configured, when causing the one or more heaters to be sequentially turned off and then on, to cause a first heater to be turned off and then on prior to testing a second heater.

10. The paving machine according to claim 8, wherein the controller is further configured, when determining to start the test, to:
determine to start the test based on:
start-up of the paving machine,
input from an operator of the paving machine via a display of the paving machine,
one or more signals from a diagnostic system of the paving machine, or
one or more signals from a server device that is remote to the paving machine.

11. The paving machine according to claim 8, wherein the controller is further configured, when receiving the measurement, to:
receive the measurement from the tester device; and
wherein the controller is further configured to:
provide the measurement to a server device remote from the paving machine for processing.

12. The paving machine according to claim 8, wherein the controller is further configured to:
generate a degradation curve based on the measurement; and
determine whether a heater is faulty or likely to experience a fault based on the degradation curve.

13. The paving machine according to claim 8, wherein the one or more actions include stopping the paving machine or a heater, or
modifying an operation of the paving machine, the heater, or one or more other heaters.

14. The paving machine according to claim 8, wherein the one or more actions include generating an alarm or a message for display on a display of the paving machine.

15. A controller for a paving machine configured to:
determine to start a test of one or more heaters associated with a screed assembly of the paving machine;
send, to a tester device associated with the paving machine, one or more signals configured to cause a test voltage to be generated while the one or more heaters are sequentially turned off and then on during the test;
receive a measurement of an insulation resistance of each of the one or more heaters during the test; and
perform one or more actions based on a result of processing the measurement.

16. The controller according to claim 15, wherein the one or more signals are further configured, when causing the one or more heaters to be sequentially turned off and then on, to cause a first heater to be turned off and then on prior to testing a second heater.

17. The controller according to claim 15, further configured, when determining to start the test, to:
determine to start the test based on:
start-up of the paving machine,
input from an operator of the paving machine via a display of the paving machine,
one or more signals from a diagnostic system of the paving machine, or
one or more signals from a server device that is remote to the paving machine.

18. The controller according to claim 15, further configured, when receiving the measurement, to:
receive the measurement from the tester device; and
wherein the controller is further configured to:
provide the measurement to a server device remote from the paving machine for processing.

19. The controller according to claim 15, further configured to:
generate a degradation curve based on the measurement; and
determine whether a heater is faulty or likely to experience a fault based on the degradation curve.

20. The controller according to claim 15, wherein the one or more actions include stopping the paving machine or a heater, or
modifying an operation of the paving machine, the heater, or one or more other heaters.
